(19) United States
(12) Patent Application Publication
(10) Pub. No.: US 2007/0077759 A1
(43) Pub. Date: Apr. 5, 2007

(54) Method for forming dielectric film and method for manufacturing semiconductor device by using the same

(75) Inventor: Naruhiko Nakanishi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/542,152

(22) Filed: Oct. 4, 2006

(30) Foreign Application Priority Data
Oct. 5, 2005 (JP) 2005-292500
Aug. 29, 2006 (JP) 2006-231523

(51) Int. Cl. H01L 21/44

(52) U.S. Cl. 438/678

(57) ABSTRACT

In a method of manufacturing a semiconductor device, a lower electrode of a capacitor is formed above a semiconductor substrate. Thermal treatment is carried out to a base layer, which includes the lower electrode, in an atomic layer deposition apparatus. A dielectric film is formed on the base layer after the thermal treatment by an atomic layer deposition method without exposing the substrate to air. An upper electrode of the capacitor is formed on the dielectric film.

### BACKGROUND OF THE INVENTION

1. Field of the Invention

The present invention relates to a technique for forming a thin film using an atomic layer deposition (ALD) method. Particularly, the present invention relates to a method for forming a dielectric film using an atomic layer deposition device and a method for manufacturing a semiconductor device.

2. Description of the Related Art

A capacitor is used as a memory cell in a DRAM (dynamic random access memory). It is important to reduce a leakage current from the capacitor in order to suppress a refresh operation and improve a data retaining characteristic in the DRAM. In order to reduce the leakage current from the capacitor, it is necessary to provide a dielectric film having no defect for the capacitor. For this purpose, first, the dielectric film is required to be chemically stably formed. Japanese Laid Open Patent Application (JP-P2001-53254A, first conventional example) discloses an unstable stoichiometry problem when a tantalum oxide film is used as the dielectric film. Thus, in the first conventional example, not the tantalum oxide film but a (TaO)₁₋ₓ(TiO)N film is used as the dielectric film. Also, when oxygen contained in the dielectric film is diffused into a lower electrode during the manufacture or during the use, defects contained in the dielectric film increase and the leakage current increases. Therefore, a surface treatment of the lower electrode is carried out in the first conventional example.

Also, the dielectric film of the capacitor has been formed on the lower electrode having a shape of high aspect ratio, as the DRAM has been more highly integrated. Therefore, an atomic layer deposition (ALD) method having excellent coverage has been used as a method for forming the dielectric film in place of a conventional chemical vapor deposition (CVD) method. A thin film is formed by increasing an atomic layer one by one in the ALD method. Thereby, the thin film in units of several nanometers can be grown to having a uniform film thickness. The method for forming the capacitor by the ALD method has been disclosed in, for example, Japanese Unexamined Patent Application (JP-P2004-56142A, second conventional example).

In conjunction with the above description, a method for forming a gate insulating film is disclosed in Japanese Laid Open Patent Application (JP-P2004-265973A, third conventional example). A silicon nitride film is formed above a substrate in order to prevent a phenomenon that boron ions doped into a gate electrode move to the substrate side through the insulating film due to the subsequent heat treatment, and a high dielectric film containing oxygen is formed thereon to form the gate insulating film.

### SUMMARY OF THE INVENTION

It is an object of the present invention to provide a technique of forming a dielectric film having few defects by an ALD method.

Another object of the present invention is to provide a technique of reducing leakage current in a capacitor.

Still another object of the present invention is to provide a technique of improving a data retaining characteristic of a DRAM.

In an aspect of the present invention, in a method of manufacturing a semiconductor device, a lower electrode of a capacitor is formed above a semiconductor substrate. Thermal treatment is carried out to a base layer, which includes the lower electrode, in an atomic layer deposition apparatus. A dielectric film is formed on the base layer after the thermal treatment by an atomic layer deposition method without exposing the substrate to air. An upper electrode of the capacitor is formed on the dielectric film.

Here, the carrying out is desirably achieved by carrying out the thermal treatment to the base layer at 500° C. or higher in an atomic layer deposition apparatus.

Also, the thermal treatment may be carried out in an inactive gas ambience. Instead, the thermal treatment may be carried out in a vacuum. The thermal treatment may be carried out in an oxidant ambience.

Also, a top layer of the base layer may be the lower electrode.

Also, when an oxidation prevention film is formed on the lower electrode between the forming the lower electrode and the carrying out the thermal treatment, a top layer of the base layer may be the oxidation prevention film.

Also, the carrying out a thermal treatment may be achieved by forming an oxide film on the lower electrode. The top layer of the base layer may be the oxide film.

Also, the oxidation prevention film may be a silicon nitride film or an oxidation prevention film is or a silicon oxy-nitride film.

Also, the dielectric film may be formed of one selected from the group consisting of aluminum oxide, hafnium oxide, HfAlO, HfSiO, HfSiON, Ta₂O₅, ZrO₂, Y₂O₃, V₂O₅, TiO₂, Nb₂O₅ and CeO₂.

In another aspect of the present invention, a method of forming a dielectric film, is achieved by providing a base layer; by carrying out a thermal treatment to the base layer in an atomic layer deposition apparatus; and by forming a dielectric film on the base layer by an atomic layer deposition method without exposing the base layer to atmosphere.

Also, the thermal treatment may be carried out at 500° C. or higher. The thermal treatment may be carried out in an inactive gas ambience.

Also, the thermal treatment is carried out in vacuum. Instead, the thermal treatment may be carried out in an oxidant ambience.

### BRIEF DESCRIPTION OF THE DRAWINGS

FIG. 1 is a sectional view showing a structure of a semiconductor device according to a first embodiment of the present invention;

FIGS. 2A to 2F are cross sectional views schematically showing a process of forming a dielectric film using an atomic layer deposition method according to the present invention; and

FIG. 3 is a cross sectional view showing a modification of a semiconductor device according to the present invention.

### DESCRIPTION OF THE PREFERRED EMBODIMENTS

Hereinafter, a method for forming a dielectric film and a method for manufacturing a semiconductor device with a capacitor according to the present invention by using the method for forming the dielectric film will be described referring to the attached drawings. A semiconductor device such as a dynamic random access memory (DRAM) is exemplified, and a capacitor manufactured of the present invention is used as a memory cell of the DRAM.

### First Embodiment

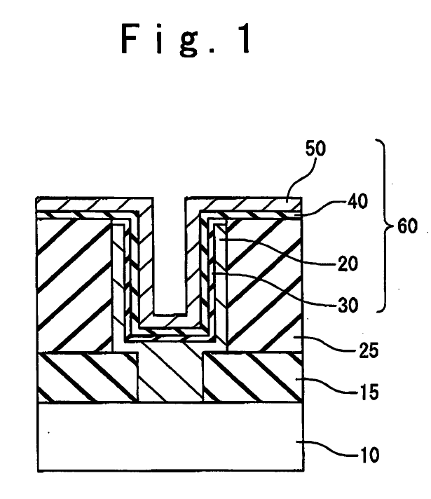

FIG. 1 is a sectional view showing a structure of a capacitor of a DRAM according to a first embodiment of the present invention. In FIG. 1, a capacitor 60 is formed on a semiconductor substrate 10 through a contact plug. The contact plug is surrounded by the interlayer insulating film 15 and the capacitor 60 is surrounded by an interlayer insulating film 25. The capacitor 60 is composed by a lower electrode 20, an oxidization prevention film 30, a dielectric film 40 and an upper electrode 50. Specifically, the dielectric film 40 is formed on the oxidization prevention film 30 which is formed on the lower electrode 20, and the upper electrode 50 is formed on the dielectric film 40.

The lower electrode 20 is formed of, for example, polysilicon. The lower electrode 20 has a cylindrical structure in order to increase a surface area. The oxidization prevention film 30 is formed from a nitrogen containing film such as a silicon nitride film. The upper electrode 50 is formed from a TiN film. The dielectric film 40 formed between the oxidization prevention film 30 and the upper electrode 50 is formed from an aluminum oxide film. One of metal oxide films such as hafnium oxide, Ta₂O₅, ZrO₂, Y₂O₃, V₂O₅, TiO₂, Nb₂O₅, and CeO₂, and a laminated film thereof may be used as material of the dielectric film 40. Also, the dielectric film 40 may be a metal oxide film such as HfAlO, HfSiO and HfSiON. As described above, the lower electrode 20 has a cylindrical crown structure, and the dielectric film 40 of the capacitor 60 is formed on the structure to have a high aspect ratio. Therefore, as described later, the dielectric film 40 according to the present embodiment is formed by the atomic layer deposition (ALD) method.

Next, a method of manufacturing the capacitor 60 of the first embodiment shown in FIG. 1 will be described below. First, the lower electrode 20 of the capacitor 60 is formed above the substrate 10. Subsequently, the nitrogen containing film such as the silicon nitride film is formed on the lower electrode 20 as the oxidization prevention film 30 to have the film thickness of about 2 nm. Subsequently, the metal oxide film as the dielectric film 40 is formed on the oxidization prevention film 30 by using the ALD method. Lastly, the TiN film as the upper electrode 50 is formed on the dielectric film 40.

In the first embodiment of the present invention, the dielectric film 40 is formed by an atomic layer deposition (ALD) apparatus (not shown). The atomic layer deposition apparatus can form a thin film on a target by the ALD method. Also, the atomic layer deposition apparatus has a heater, which can apply a high temperature to the target.

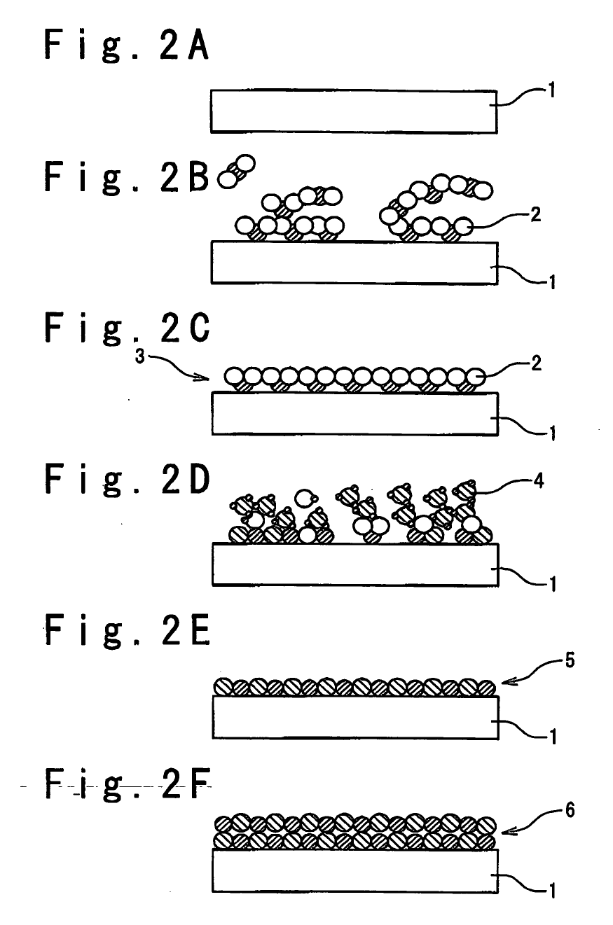

FIGS. 2A to 2F show the forming process of the dielectric film 40 by the ALD method schematically. The dielectric film 40 is formed on a predetermined base layer 1. According to the present embodiment, the base layer 1 is the lower electrode 20 and the oxidization prevention film 30, and the surface of the base layer 1 is the oxidization prevention film 30.

First, the semiconductor substrate 10 on which the base layer 1 has been formed is located in a chamber of the atomic layer deposition apparatus. Subsequently, as shown in FIG. 2A, the base layer 1 is heat treated in the atomic layer deposition apparatus. The heat treatment is carried out at the temperature of about 500 to 600° C. The heat treatment is carried out in the ambience of inert gas such as a nitrogen gas and an argon gas. Alternately, the heat treatment may be carried out in a vacuum. Thus, in the heat treatment, the semiconductor substrate 10 is not exposed to an oxygen ambience. Water and organic material absorbed on the surface of the base layer 1 are removed by the heat treatment, and “degasifying treatment” to the water and organic matter is carried out.

After the heat treatment, the forming process of the dielectric film 40 is carried out without opening the chamber of the atomic layer deposition apparatus to the air. That is, the dielectric film 40 is formed on the base layer 1 without exposing it to the air after the heat treatment. Thus, the dielectric film 40 is formed on the clean surface of the base layer 1.

As the dielectric film 40, for example, an aluminum oxide film is formed. The aluminum oxide film is formed at the temperature of 400° C. in the atomic layer deposition apparatus by the ALD method. As a material of the aluminum oxide, for example, TMA (trimethyl aluminum) is used. O₃ gas is used as a material gas required for oxidation reaction. More specifically, as shown in FIG. 2B, TMA (first substance) 2 is first introduced into the chamber. Thereby, the TMA 2 is chemically adsorbed on the surface of the base layer 1. The TMA 2 which was not absorbed is discharged from the chamber by a purge or vacuum purge. As a result, as shown in FIG. 2C, a TMA film (first substance film) 3 is formed on the surface of the base layer 1.

Next, as shown in FIG. 2D, O₃ gas (second substance) 4 is introduced into the chamber as a material gas capable of generating oxygen radicals. The O₃ gas 4 is chemically reacted with the TMA film 3, and thereby the aluminum oxide is formed as the metal oxide. Substances which are not deposited on the base layer 1 such as hydrogen and carbon which are contained in the TMA 2 are discharged from the chamber by the purge or the vacuum purge by using an inert gas. As a result, as shown in FIG. 2E, an aluminum oxide film (metal oxide film) 5 is formed on the surface of the base layer 1. The metal oxide film 5 is an atomic layer having the film thickness of about the atomic size of a desired substance.

Hereinafter, the aluminum oxide film 5 is deposited in order by alternately supplying the TMA 2 and the O₃ gas 4 and repeating the same process. As a result, as shown in FIG. 2F, a dielectric film 6 having a desired film thickness is formed on the base layer 1.

Although the aluminum oxide film is exemplified in the above description, the dielectric film 6 formed by the ALD method may be one of the metal oxide films such as hafnium oxide, Ta₂O₅, ZrO₂, Y₂O₃, V₂O₃, TiO₂, Nb₂O₅ and CeO₂ or the like, or the laminated film thereof. The dielectric film 6 formed by the ALD method may be the metal oxide film such as HfAlO, HfSiO and HfSiON.

In the present embodiment, the silicon nitride film as the oxidization prevention film 30 is previously formed on the lower electrode 20. When the dielectric film is then formed, the semiconductor substrate is placed in the atomic layer deposition apparatus, where the surface treatment is carried out to remove a natural oxide film or the like. Then, the dielectric film is formed on the oxidization prevention film without exposing to the air. In Japanese Laid Open Patent Application (JP-P2001-53254A), after a substrate is placed in an LPCVD device, the surface treatment is carried out. A silicon nitride film is formed, and a dielectric film is then formed. Japanese Laid Open Patent Application (JP-P2004-265973A) is also the same. Therefore, the manufacturing process in the present embodiment is different from those of the conventional techniques.

The water and the organic film are absorbed on the surface of the base layer 1 before the formation of the dielectric film 40. The water and the organic matter are not degasified in the low temperature heat treatment of 500° C. or less. The temperature during the formation of the dielectric film using the ALD method is generally 500° C. or less, and the water and the organic film are not removed in the usual process under the low temperature. In this case, the dielectric film is formed on the surface of the base layer 1 on which the water and the organic film are absorbed. This causes the generation of the defects in the interface between the base layer 1 and the dielectric film to be formed.

According to the present embodiment, the base layer 1 is heat treated at about 500 to 600° C. as the pretreatment of the formation of the dielectric film 40. The water and organic film absorbed on the surface of the base layer 1 are removed by the heat treatment at this temperature. The dielectric film 40 is then continuously formed on the base layer 1 by the ALD method without exposing to the air. That is, the dielectric film 40 is formed on the clean surface of the base layer 1. Thus, the generation of the defects in the interface between the base layer 1 and the dielectric film 40 is prevented.

In this way, according to the present embodiment, the dielectric film 40 having few defects can be formed by the ALD method. Therefore, the leakage current in the capacitor 60 containing the dielectric film 40 is reduced. In the DRAM using the capacitor 60 as the memory cell, the number of times of the refreshing operation is reduced and the data retaining characteristic is improved. Also, since a refresh operation is suppressed, the power consumption of the DRAM is reduced.

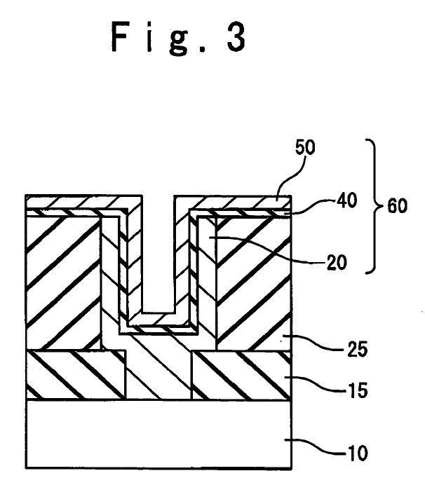

Next, a modification of the first embodiment will be described below. The capacitor 60 may have an MIM (Metal-Insulator-Metal) structure. The capacitor 60 having the MIM structure is shown in FIG. 3. The oxidization prevention film 30 is omitted in comparison with the structure shown in FIG. 1. That is, the dielectric film 40 is formed on the lower electrode 20, and the upper electrode 50 is formed on the dielectric film 40. The lower electrode 20 is formed from a TiN film. Examples of the dielectric film 40 formed by the ALD method include one of the metal oxide film such as aluminum oxide, hafnium oxide, Ta₂O₅, ZrO₂, Y₂O₃, V₂O₅, TiO₂, Nb₂O₅, CeO₂, HfAlO, HfSiO, and HfSiON, and the laminated film thereof. The upper electrode 50 is formed from a TiN film.

The dielectric film 40 is formed in accordance with the same process as that shown in FIGS. 2A to 2F. However, according to the present modification, the surface of the base layer 1 is the lower electrode 20. Even in this case, the dielectric film 40 having few defects is similarly formed. Therefore, the leakage current in the capacitor 60 containing the dielectric film 40 is reduced. The data retaining characteristic of the DRAM using the capacitor 60 as the memory cell is improved, and the power consumption of the DRAM is reduced.

### Second Embodiment

Next, a manufacturing method of a capacitor of the semiconductor device according to a second embodiment of the present invention will be described. The semiconductor device of the second embodiment has the same structure as that of the first embodiment. In the second embodiment, an oxide silicon film or a silicon oxynitride film is formed as the oxidization prevention film 30 on the lower electrode 20 in order to prevent the diffusion of oxygen from the dielectric film 40. That is, as a pretreatment for forming the aluminum oxide film by the ALD method, a base layer 1 is heat treated in an oxygen ambience at about 500 to 600° C. in the atomic layer deposition apparatus. A silicon oxide film having few defects is previously formed on the base layer 1 containing the lower electrode 20 so that the oxide silicon film has the film thickness of 2 nm. Then, the aluminum oxide film is formed on the oxide film having few defects in the same manner as in the first embodiment. As described above, the aluminum oxide film is formed at 400° C. by using the TMA and the O₃ gas. Oxygen (O₂) gas is used for the heat treatment according to the present embodiment. An RTP (rapid heating) apparatus can be used for a thermal treatment equipment. Thus, the reduction of the leakage current can be attained. N₂O as, NO gas, and O₃ gas may be used for the oxygen (oxidization) ambience. A diffusion furnace may be used for the thermal treatment equipment.

The water and the organic film are absorbed on the surface of the base layer before the formation of the dielectric film by the ALD method, and the natural oxide film is formed. Thereby, the dielectric film is formed on the surface of the base layer on which the natural oxide film is formed. The oxide film layer having many defects is formed in the interface between the base layer and the dielectric film, and a capacitor having high leakage current is easily formed. Or, the oxygen contained in the dielectric film is diffused into the base layer at the time of forming the dielectric film (oxide film) or at the following heat treatment, and the oxide film layer having many defects is easily formed in the interface between the base layer and the dielectric film. In the present embodiment, a heat treatment of exposing the base layer to an oxygen (oxidization) ambience is carried out as the pretreatment of the formation of the dielectric film by the ALD method. The oxide film having few defects in the interface between the base layer and the dielectric film is formed through the heat treatment. Therefore, since the oxygen contained in the dielectric film is hardly diffused to the lower electrode, a capacitor having low leakage current can be formed.

According to the present invention, the dielectric film is formed by the ALD method. The base layer is heat treated in the atomic layer deposition apparatus as the pretreatment of the formation of the dielectric film. Water and an organic film absorbed on the surface of the base layer are removed by the heat treatment. The dielectric film is then formed on the base layer without exposing to the air. That is, the dielectric film is formed on the clean surface of the base layer. Thus, the generation of the defects is prevented in the interface between the base layer and the dielectric film.

According to the present invention, the dielectric film having few defects can be formed by the ALD method. Therefore, the leakage current in the capacitor containing the dielectric film is reduced. In the DRAM using the capacitor as the memory cell, the number of times of a refresh operation is reduced and a data retaining characteristic is improved. Also, since the refresh operation is suppressed, the power consumption of the DRAM is reduced.

What is claimed is:

1. A method of manufacturing a semiconductor device, comprising:
forming a lower electrode of a capacitor above a semiconductor substrate;
carrying out a thermal treatment to a base layer, which includes said lower electrode, in an atomic layer deposition apparatus;
forming a dielectric film on said base layer after the thermal treatment by an atomic layer deposition method without exposing said substrate to air; and
forming an upper electrode of said capacitor on said dielectric film.

2. The method according to claim 1, wherein said carrying out comprises:
carrying out said thermal treatment to said base layer at 500° C. or higher in an atomic layer deposition apparatus.

3. The method according to claim 1, wherein said thermal treatment is carried out in an inactive gas ambience.

4. The method according to claim 1, wherein said thermal treatment is carried out in a vacuum.

5. The method according to claim 1, wherein said thermal treatment is carried out in an oxidant ambience.

6. The method according to claim 1, wherein a top layer of said base layer is said lower electrode.

7. The method according to claim 1, further comprising:
forming an oxidation prevention film on said lower electrode between said forming said lower electrode and said carrying out said thermal treatment,
wherein a top layer of said base layer is said oxidation prevention film.

8. The method according to claim 5, wherein said carrying out a thermal treatment comprises:
forming an oxide film on said lower electrode, and
a top layer of said base layer is said oxide film.

9. The method according to claim 7, wherein said oxidation prevention film is a silicon nitride film or an oxidation prevention film is or a silicon oxynitride film.

10. The method according to claim 1, wherein said dielectric film is formed of one selected from the group consisting of aluminum oxide, hafnium oxide, HfAlO, HfSiO, HfSiON, Ta₂O₅, ZrO₂, Y₂O₃, V₂O₅, TiO₂, Nb₂O₅ and CeO₂.

11. A method of forming a dielectric film, comprising:
providing a base layer;
carrying out a thermal treatment to said base layer in an atomic layer deposition apparatus; and
forming a dielectric film on said base layer by an atomic layer deposition method without exposing said base layer to atmosphere.

12. The method according to claim 11, wherein said thermal treatment is carried out at 500° C. or higher.

13. The method according to claim 11, wherein said thermal treatment is carried out in an inactive gas ambience.

14. The method according to claim 11, wherein said thermal treatment is carried out in vacuum.

15. The method according to claim 11, wherein said thermal treatment is carried out in an oxidant ambience.
